(19) United States
(12) Patent Application Publication
(10) Pub. No.: US 2025/0234718 A1
(43) Pub. Date: Jul. 17, 2025

(54) DISPLAY PANEL AND METHOD FOR MANUFACTURING THE SAME

(71) Applicant: Samsung Display Co., Ltd., Yongin-si (KR)

(72) Inventors: DAEWON CHOI, Yongin-si (KR); Taesang PARK, Yongin-si (KR); CHANGHO YI, Yongin-si (KR); YU-GWANG JEONG, Yongin-si (KR)

(73) Assignee: Samsung Display Co., Ltd., Yongin-si (KR)

(21) Appl. No.: 18/971,562

(22) Filed: Dec. 6, 2024

(30) Foreign Application Priority Data
Jan. 12, 2024 (KR) 10-2024-0005659

(51) Int. Cl. H10K 59/122; H10K 59/12; H10K 59/80

(52) U.S. Cl. CPC H10K 59/122; H10K 59/1201; H10K 59/873

(57) ABSTRACT

Disclosed is a display panel including a base layer, a pixel defining film disposed on the base layer and including a light-emitting opening, a bank disposed on the pixel defining film and including a bank opening overlapping the light-emitting opening, and a light-emitting element including an anode, a light-emission pattern, and a cathode in contact with the bank, wherein the light-emitting element is disposed in the light-emitting opening and the bank opening. The bank includes a first bank layer disposed on the pixel defining film, and a second bank layer disposed on the first bank layer and having an inverse-tapered shape.

### CROSS-REFERENCE TO RELATED APPLICATION(S)

This application claims priority under 35 U.S.C. § 119 to Korean Patent Application No. 10-2024-0005659 filed on Jan. 12, 2024, in the Korean Intellectual Property Office, the disclosures of which are incorporated by reference herein in their entireties.

### BACKGROUND

### 1. Technical Field

Embodiments described herein relate to a display panel and a method for manufacturing the display panel, and more particularly, relate to a display panel with improved display quality.

### 2. Description of the Related Art

A display device such as a television, a monitor, a smartphone, and a tablet that provides an image to a user includes a display panel that displays the image. Various display panels such as a liquid crystal display panel, an organic light-emitting display panel, an electro wetting display panel, and an electrophoretic display panel are being developed.

The organic light-emitting display panel may include an anode, a cathode, and a light-emitting pattern. The light-emitting pattern may be separated for each light-emitting area, and the cathode may provide a common voltage to the light-emitting areas.

### SUMMARY

Embodiments provide a display panel with improved display quality in which a light-emitting element is formed without using a metal mask, and a method for manufacturing the display panel.

According to an embodiment, a display panel may include a base layer, a pixel defining film disposed on the base layer and including a light-emitting opening, a bank disposed on the pixel defining film and including a bank opening overlapping the light-emitting opening, and a light-emitting element including an anode, a light-emission pattern, and a cathode in contact with the bank, wherein the light-emitting element is disposed in the light-emitting opening and the bank opening. The bank may include a first bank layer disposed on the pixel defining film, and a second bank layer disposed on the first bank layer and having an inverse-tapered shape.

The second bank layer may include a tip portion protruding from the first bank layer.

The second bank layer may include a lower surface extending from a first inner surface of the first bank layer, a second inner surface extending from the lower surface in a direction away from the base layer, and an upper surface extending from the second inner surface in a direction parallel to the lower surface, and an angle formed between the lower surface and the second inner surface may be an obtuse angle.

A light-emitting area, in which the anode is exposed, may be defined by the light-emitting opening, and the second inner surface may be closer to a center portion of the light-emitting area than the first inner surface.

A length in a direction of the upper surface of the second bank layer may be greater than a length in the direction of the lower surface, and the direction may be perpendicular to a thickness direction of the base layer.

The display panel may further include a lower encapsulation inorganic pattern covering the light-emitting element, and the lower encapsulation inorganic pattern may be in contact with an entirety of the second inner surface of the second bank layer.

The display panel may further include an encapsulation organic film covering the lower encapsulation inorganic pattern.

The second bank layer may include a plurality of sub-layers.

An etch rate of a sub-layer adjacent to the first bank layer may be greater than an etch rate of a sub-layer adjacent to the encapsulation organic film.

A length in a direction of a sub-layer adjacent to the first bank layer may be smaller than a length in the direction of a sub-layer adjacent to the encapsulation organic film, and the direction may be perpendicular to a thickness direction of the base layer.

The second bank layer may contain an inorganic material.

A density of the second bank layer may decrease in a direction toward the first bank layer from the encapsulation organic film.

According to another embodiment, a method for manufacturing a display panel may include providing a preliminary display panel including a base layer and a pixel defining film disposed on the base layer, forming a first preliminary bank layer on the preliminary display panel, forming a second preliminary bank layer on the first preliminary bank layer, etching the first and second preliminary bank layers to form a bank including a bank opening and a portion including an inverse-tapered shape, etching the pixel defining film to define a light-emitting opening overlapping the bank opening, and forming a light-emitting element in the light-emitting opening and the bank opening.

The etching of the first and second preliminary bank layers to form the bank including the bank opening and the portion having the inverse-tapered shape may include forming a first bank layer and a second bank layer, wherein a length in a direction of an upper surface of the second bank layer is greater than a length in the direction of a lower surface and the direction is perpendicular to a thickness direction of the base layer.

The forming of the second preliminary bank layer on the first preliminary bank layer may include depositing a first sub-layer on the first preliminary bank layer, depositing a second sub-layer on the first sub-layer, and depositing a third sub-layer on the second sub-layer, and an etch rate of the first sub-layer may be greater than an etch rate of the second sub-layer, and the etch rate of the second sub-layer may be greater than an etch rate of the third sub-layer.

The etching of the first and second preliminary bank layers to form the bank including the bank opening may include dry etching the first and second preliminary bank layers to define a preliminary bank opening, and wet etching the first and second preliminary bank layers to form a first bank layer and a second bank layer having an inverse-tapered shape.

The forming of the second preliminary bank layer on the first preliminary bank layer may include depositing an inorganic material at a first speed, and depositing the inorganic material at a second speed, and the first speed may be higher than the second speed.

A density of the second preliminary bank layer may increase in a direction away from the first preliminary bank layer.

The etching of the first and second preliminary bank layers to form the bank including the bank opening may include dry etching the first and second preliminary bank layers to form a second bank layer having an inverse-tapered shape, and wet etching the first preliminary bank layer to form a first bank layer.

The bank opening may include a first area defined by a first inner surface of the first bank layer and a second area defined by a second inner surface of the second bank layer, and a length in a direction perpendicular to the base layer of the first area may be greater than a length in the direction perpendicular to the base layer of the second area.

### BRIEF DESCRIPTION OF THE FIGURES

The above and other objects and features of the disclosure will become apparent by describing in detail embodiments thereof with reference to the accompanying drawings.

FIG. 1A is a schematic perspective view of a display device according to an embodiment.

FIG. 1B is an exploded schematic perspective view of a display device according to an embodiment.

FIG. 2 is a schematic cross-sectional view of a display module according to an embodiment.

FIG. 3 is a schematic plan view of a display panel according to an embodiment.

FIG. 4 is a schematic plan view enlarging a portion of a display area of a display panel according to an embodiment.

FIG. 5 is a schematic cross-sectional view cut along a line I-I′ in FIG. 3.

FIG. 6A is an enlarged schematic view of an area corresponding to an area AA′ in FIG. 5.

FIG. 6B is an enlarged schematic view of an area corresponding to an area AA′ in FIG. 5.

FIGS. 7A to 7J are schematic cross-sectional views showing some of steps of a display panel manufacturing method according to an embodiment.

FIGS. 8A to 8C are schematic cross-sectional views showing some of steps of a display panel manufacturing method according to an embodiment.

FIGS. 9A to 9C are schematic cross-sectional views showing some of steps of a display panel manufacturing method according to an embodiment.

### DETAILED DESCRIPTION OF THE EMBODIMENTS

As used herein, when a component (or a region, a layer, a portion, and the like) is referred to as being “on”, “connected to”, or “coupled to” another component, it means that the component may be directly disposed/connected/coupled on another component or a third component may be disposed between the component and another component.

Like reference numerals refer to like components. For example, in the drawings, thicknesses, ratios, and dimensions of components are exaggerated for effective description of technical content. “and/or” includes all of one or more combinations that the associated components may define.

Terms such as first, second, and the like may be used to describe various components, but the components should not be limited by the terms. The above terms are used only for the purpose of distinguishing one component from another. For example, without departing from the scope of the disclosure, a first component may be named as a second component, and similarly, the second component may also be named as the first component. The singular expression includes the plural expression unless the context clearly dictates otherwise.

For example, terms such as “beneath”, “below”, “on”, “above” are used to describe the relationship of the components illustrated in the drawings. The above terms are relative concepts, and are described with reference to directions indicated in the drawings.

It should be understood that terms such as “include” or “have” are intended to specify that a feature, a number, a step, an operation, a component, a part, or a combination thereof described herein is present, and do not preclude a possibility of addition or existence of one or more other features or numbers, steps, operations, components, parts, or combinations thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described with reference to the drawings.

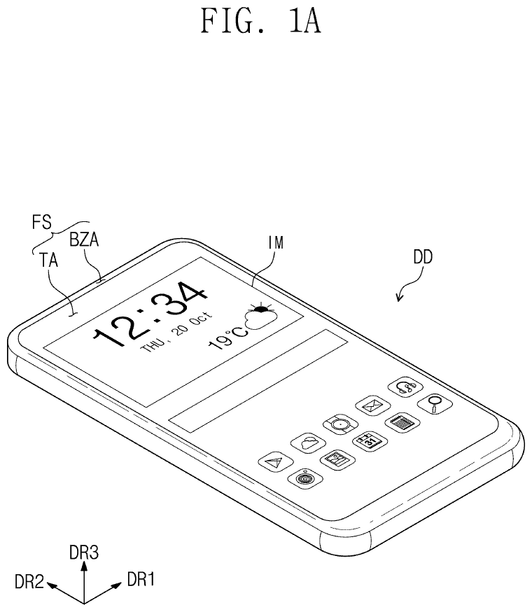

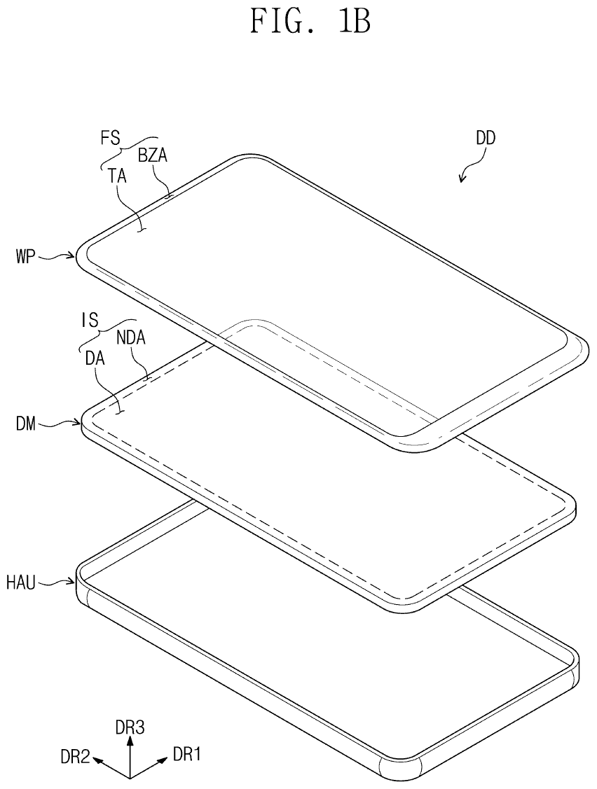

FIG. 1A is a schematic perspective view of a display device DD according to an embodiment, and FIG. 1B is an exploded schematic perspective view of the display device DD according to an embodiment.

In an embodiment, the display device DD may be a large electronic device such as a television, a monitor, or an external billboard. For example, the display device DD may be a small or medium-sized electronic device such as a personal computer, a laptop computer, a personal digital terminal, a vehicle navigation unit, a game console, a smartphone, a tablet, and a camera. However, this is an example, and the display device DD may be implemented as other display devices as long as it does not deviate from a concept of the disclosure. FIGS. 1A and 1B show that the display device DD is the smart phone as an example.

Referring to FIGS. 1A and 1B, the display device DD may display an image IM in a third direction DR3 on a display surface FS parallel to each of a first direction DR1 and a second direction DR2. The image IM may include a static image as well as a dynamic image. In FIG. 1A, a watch window and icons are shown as an example of the image IM. The display surface FS on which the image IM is displayed may correspond to a front surface of the display device DD.

In an embodiment, a front surface (or a top surface) and a rear surface (or a bottom surface) of each member are defined based on the direction in which the image IM is displayed. The front surface and the rear surface face each other in the third direction DR3, and a normal direction of each of the front surface and the rear surface may be parallel to the third direction DR3. In an example, directions indicated by the first to third directions DR1, DR2, and DR3 are relative concepts and are able to be converted to other directions. Herein, “on a plane” or “in plan view” may mean when viewed in the third direction DR3.

The display device DD may include a window WP, a display module DM, and a housing HAU. The window WP and the housing HAU may be coupled to each other to form an outer appearance of the display device DD.

The window WP may include an optically transparent insulating material. For example, the window WP may include glass or plastic. A front surface of the window WP may define the display surface FS of the display device DD. The display surface FS may include a transmissive area TA and a bezel area BZA. The transmissive area TA may be an optically transparent area. For example, the transmissive area TA may be an area with visible light transmittance equal to or greater than about 90%.

The bezel area BZA may be an area with relatively low light transmittance compared to the transmissive area TA. The bezel area BZA may define a shape of the transmissive area TA. The bezel area BZA may be adjacent to the transmissive area TA and may surround the transmissive area TA. In another example, the bezel area BZA of the window WP is able to be omitted. The window WP may include at least one functional layer among an anti-fingerprint layer, a hard coating layer, and an anti-reflection layer, and may not be limited to any one embodiment.

The display module DM may be disposed under the window WP. The display module DM may be a component that actually generates the image IM. The image IM generated by the display module DM is displayed on a display surface IS of the display module DM and is recognized externally by a user via the transmissive area TA.

The display module DM may include a display area DA and a non-display area NDA. The display area DA may be an area activated in response to an electrical signal. The non-display area NDA may be adjacent to the display area DA. The non-display area NDA may surround the display area DA. The non-display area NDA, as an area covered by the bezel area BZA, may not be visible from the outside.

The housing HAU may be coupled with the window WP. The housing HAU may be coupled with the window WP to provide a selected internal space. The display module DM may be accommodated in the internal space.

The housing HAU may include a material with relatively high rigidity. For example, the housing HAU may include frames and/or plates including glass, plastic, or metal, or a combination thereof. The housing HAU may reliably protect components of the display device DD accommodated in the internal space from an external impact.

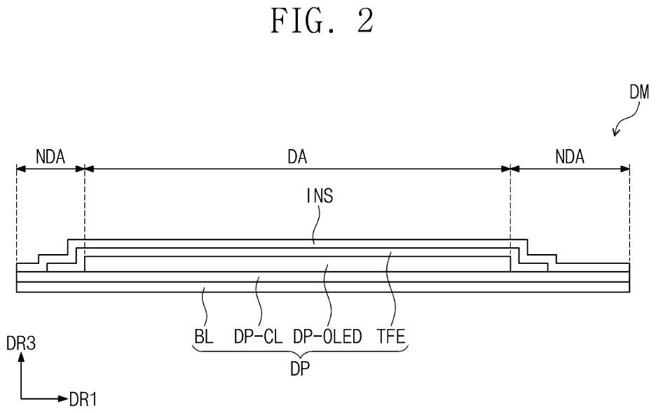

FIG. 2 is a schematic cross-sectional view of the display module DM according to an embodiment.

Referring to FIG. 2, the display module DM may include a display panel DP and an input sensor INS. For example, the display device DD (see FIG. 1A) according to an embodiment may further include a protective member disposed on a bottom surface (or lower surface) of the display panel DP or an anti-reflection member disposed on a top surface of the input sensor INS, and/or a window member.

The display panel DP may be a light-emitting display panel. However, this is an example and embodiments are not limited thereto. For example, the display panel DP may be an organic light-emitting display panel or an inorganic light-emitting display panel. A light-emitting layer within the organic light-emitting display panel may include an organic light-emitting material. A light-emitting layer within the inorganic light-emitting display panel may include a quantum dot, a quantum rod, or a micro LED. Hereinafter, the display panel DP will be described as the organic light-emitting display panel.

The display panel DP may include a base layer BL, a circuit element layer DP-CL disposed on the base layer BL, a display element layer DP-OLED, and a thin film encapsulation layer TFE. The input sensor INS may be disposed (e.g., directly disposed) on the thin film encapsulation layer TFE. As used herein, “a component A being disposed directly on a component B” means that an adhesive layer is not disposed between the component A and the component B.

The base layer BL may include at least one plastic film. The base layer BL, as a flexible substrate, may include a plastic substrate, a glass substrate, a metal substrate, an organic/inorganic composite material substrate, or the like. The display area DA and the non-display area NDA described in FIG. 1B may be defined identically in the base layer BL.

The circuit element layer DP-CL may include at least one insulating layer and a circuit element. The insulating layer may include at least one inorganic layer and at least one organic layer. The circuit element may include signal lines, a driving circuit of a pixel, or the like.

The display element layer DP-OLED may include a partition wall (or bank) and a light-emitting element. The light-emitting element may include an anode, an intermediate layer, and a cathode.

The thin film encapsulation layer TFE may include thin films. Some thin films may be disposed to improve optical efficiency, and some thin films may be disposed to protect organic light-emitting diodes.

The input sensor INS may obtain coordinate information of an external input. The input sensor INS may have a multi-layer structure. The input sensor INS may include a single conductive layer or a multi-layer conductive layer. For example, the input sensor INS may include a single insulating layer or a multi-layer insulating layer. The input sensor INS may sense an external input using a capacitance scheme. However, this is an example and embodiments are not limited thereto. For example, in an embodiment, the input sensor INS may sense the external input using an electromagnetic induction scheme or a pressure sensing scheme. In an example, in another embodiment, the input sensor INS may be omitted.

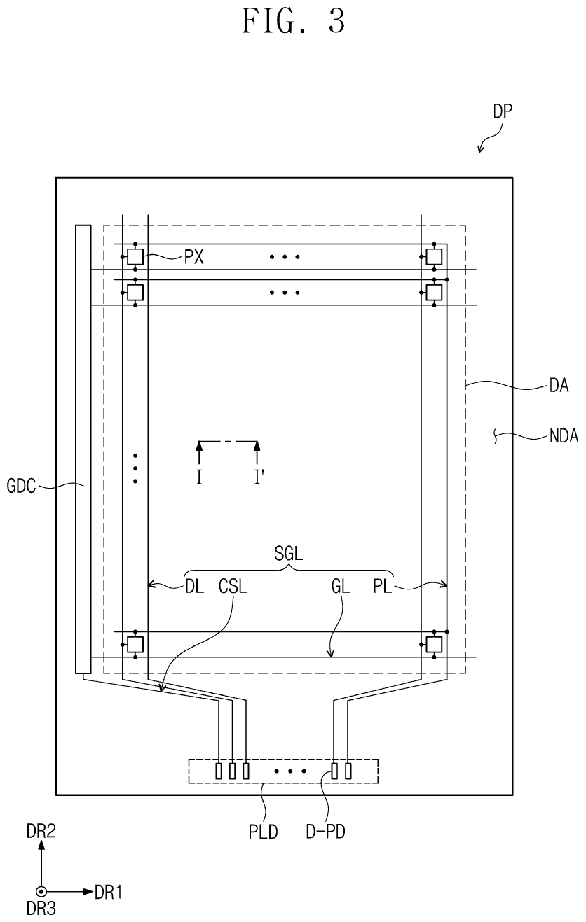

FIG. 3 is a schematic plan view of a display panel according to an embodiment.

Referring to FIG. 3, the display area DA and the non-display area NDA around the display area DA may be defined in the display panel DP. The display panel DP may include pixels PX and signal lines SGL electrically connected to the pixels PX. The display panel DP may include a driving circuit GDC and a pad PLD. The display area DA and the non-display area NDA may be distinguished from each other by presence or absence of arrangement of the pixels PX. The pixels PX may be arranged in the display area DA. The driving circuit GDC and the pad PLD may be disposed in the non-display area NDA.

The pixels PX may be arranged in the first direction DR1 and the second direction DR2. The pixels PX may include pixel rows extending in the first direction DR1 and arranged in the second direction DR2 and pixel columns extending in the second direction DR2 and arranged in the first direction DR1.

The signal lines SGL may include gate lines GL, data lines DL, a power line PL, and a control signal line CSL. Each of the gate lines GL may be connected to a pixel corresponding thereto among the pixels PX, and each of the data lines DL may be connected to a pixel corresponding thereto among the pixels PX. The power line PL may be electrically connected to the pixels PX. The control signal line CSL may be connected to the driving circuit GDC and provide control signals to the driving circuit GDC.

The driving circuit GDC may include a gate driving circuit. The gate driving circuit may generate gate signals and sequentially output the generated gate signals to the gate lines GL. The gate driving circuit may further output another control signal to the pixel driving circuit.

The pad PLD may be a portion where a flexible circuit board is connected. The pad PLD may include pixel pads D-PD, and the pixel pads D-PD may be pads for connecting the flexible circuit board to the display panel DP. Each of the pixel pads D-PD may be connected to a signal line corresponding thereto among the signal lines SGL. The pixel pads D-PD may be connected to the pixels PX corresponding thereto via the signal lines SGL. For example, one of the pixel pads D-PD may be connected to the driving circuit GDC.

For example, the pad PLD may further include input pads. The input pads may be pads for connecting the flexible circuit board to the input sensor INS (see FIG. 2). However, embodiments are not limited thereto, and the input pads may be disposed on the input sensor INS (see FIG. 2) and connected to a circuit board separated from the pixel pads D-PD. In another example, the input sensor INS (see FIG. 2) may be omitted and the input pads may not be further included.

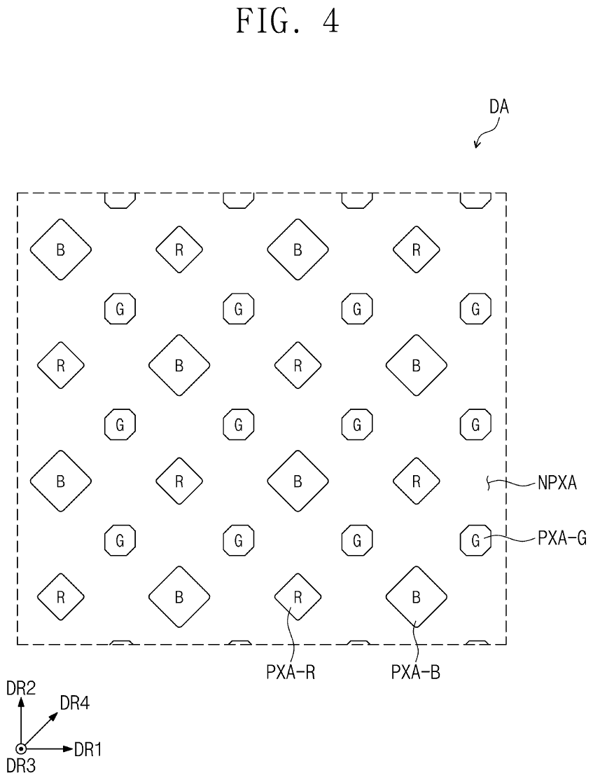

FIG. 4 is a schematic plan view enlarging a portion of the display area DA of the display panel DP (see FIG. 2) according to an embodiment. FIG. 4 shows a plane of the display module DM viewed from above the display surface IS (see FIG. 1B) of the display module DM (see FIG. 1B), and shows arrangement of light-emitting areas PXA-R, PXA-G, and PXA-B.

Referring to FIG. 4, the display area DA may include the first to third light-emitting areas PXA-R, PXA-G, and PXA-B and a peripheral area NPXA surrounding the first to third light-emitting areas PXA-R, PXA-G, and PXA-B. The first to third light-emitting areas PXA-R, PXA-G, and PXA-B may correspond to areas where light provided from the light-emitting elements is emitted. The first to third light-emitting areas PXA-R, PXA-G, and PXA-B may be distinguished from each other based on a color of light emitted toward the outside of the display module DM (see FIG. 2).

The first to third light-emitting areas PXA-R, PXA-G, and PXA-B may provide first to third color light having different colors, respectively. For example, first color light may be red light, second color light may be green light, and third color light may be blue light. However, examples of first to third color light are not limited to the above examples.

Each of the first to third light-emitting areas PXA-R, PXA-G, and PXA-B may be defined as an area where a top surface (or upper surface) of each anode is exposed by a light-emitting opening, which will be described later. The peripheral area NPXA may set boundaries of the first to third light-emitting areas PXA-R, PXA-G, and PXA-B and may prevent color mixing therebetween.

The first to third light-emitting areas PXA-R, PXA-G, and PXA-B may include first light-emitting areas, second light-emitting areas, and third light-emitting areas repeatedly arranged in a selected arrangement within the display area DA, respectively. For example, each of the first light-emitting areas PXA-R and each of the third light-emitting areas PXA-B may be arranged alternately along the first direction DR1 to form a ‘first group’. Each of the second light-emitting areas PXA-G may be arranged along the first direction DR1 to form a ‘second group’. The ‘first group’ and the ‘second group’ may include first groups and second groups, respectively, and the ‘first groups’ and the ‘second groups’ may be arranged alternately with each other along the second direction DR2.

The one second light-emitting area PXA-G may be disposed to be spaced apart from the one first light-emitting area PXA-R or the one third light-emitting area PXA-B in a fourth direction DR4. The fourth direction DR4 may be defined as a direction between the first direction DR1 and the second direction DR2.

FIG. 4 shows the arrangement of the first to third light-emitting areas PXA-R, PXA-G, and PXA-B as an example. Embodiments are not limited thereto and the first to third light-emitting areas PXA-R, PXA-G, and PXA-B may be arranged in various forms. In an embodiment, the first to third light-emitting areas PXA-R, PXA-G, and PXA-B may have a PENTILE™ arrangement as shown in FIG. 4. In another example, the first to third light-emitting areas PXA-R, PXA-G, and PXA-B may have a stripe arrangement or a Diamond Pixel™ arrangement.

The first to third light-emitting areas PXA-R, PXA-G, and PXA-B may have various shapes on a plane (or in plan view). For example, the first to third light-emitting areas PXA-R, PXA-G, and PXA-B may have shapes such as a polygonal, circular, or oval shape. FIG. 4 shows the first and third light-emitting areas PXA-R and PXA-B having a square shape (or a diamond shape) and the second light-emitting area PXA-G having an octagonal shape on the plane.

The first to third light-emitting areas PXA-R, PXA-G, and PXA-B may have the same shape on the plane or at least some of them may have different shapes. FIG. 4 shows the first and third light-emitting areas PXA-R and PXA-B having the same shape on the plane and the second light-emitting area PXA-G having a shape different from that of the first and third light-emitting areas PXA-R and PXA-B as an example.

At least some of the first to third light-emitting areas PXA-R, PXA-G, and PXA-B may have different area sizes on the plane. In an embodiment, an area size of the first light-emitting area PXA-R that emits red light may be greater than an area size of the second light-emitting area PXA-G that emits green light and smaller than an area size of the third light-emitting area PXA-B that emits blue light. However, a size relationship between the area sizes of the first to third light-emitting areas PXA-R, PXA-G, and PXA-B depending on the colors of emitted light may not be limited thereto and may vary depending on a design of the display module DM (see FIG. 2). For example, the first to third light-emitting areas PXA-R, PXA-G, and PXA-B may have the same area size on the plane without being limited thereto.

In an example, the shapes, the area sizes, and the arrangements of the first to third light-emitting areas PXA-R, PXA-G, and PXA-B of the display module DM (see FIG. 2) may be designed in various ways depending on the colors of emitted light or a size and a configuration of the display module DM (see FIG. 2), and may not be limited to the embodiment shown in FIG. 4.

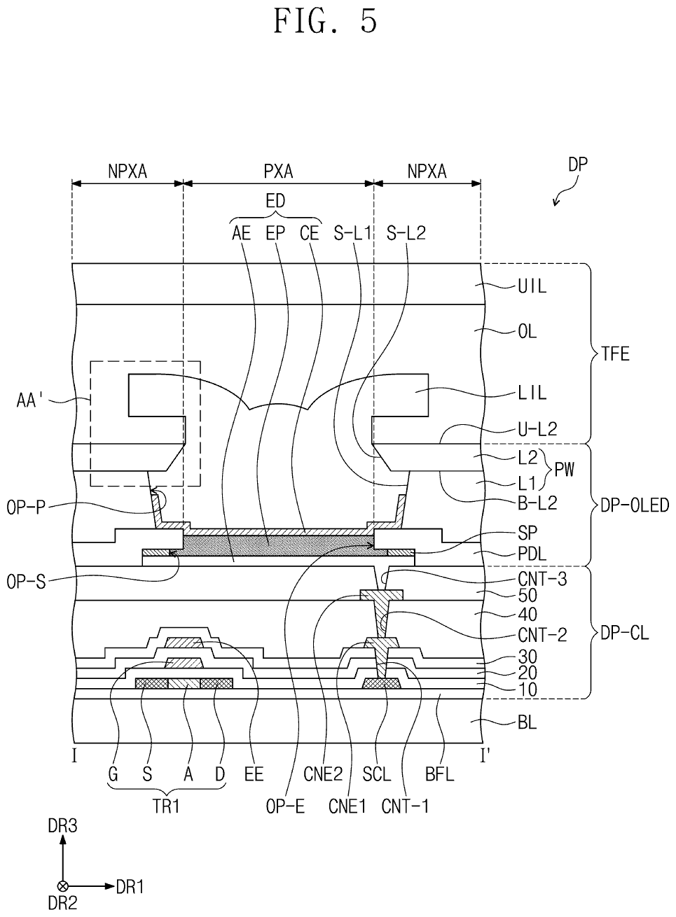

FIG. 5 is a schematic cross-sectional view of a display panel cut along a line I-I′ in FIG. 3. In describing FIG. 5, the description will be made with reference to FIG. 2, and description of the same reference numerals will be omitted. FIG. 5 is an enlarged schematic view of the one light-emitting area PXA in the display area DA (see FIG. 4). The light-emitting area PXA in FIG. 5 may correspond to one of the first to third light-emitting areas PXA-R, PXA-G, and PXA-B in FIG. 4.

Referring to FIG. 5, the display panel DP may include the base layer BL, the circuit element layer DP-CL, the display element layer DP-OLED, and the thin film encapsulation layer TFE.

The display panel DP may include insulating layers, a semiconductor pattern, a conductive pattern, a signal line, and the like. The insulating layer, a semiconductor layer, and a conductive layer are formed via a scheme such as coating and deposition. Thereafter, the insulating layer, the semiconductor layer, and the conductive layer may be selectively patterned via photolithography and etching. With such scheme, the semiconductor pattern, the conductive pattern, the signal line, and the like included in the circuit element layer DP-CL and the display element layer DP-OLED may be formed.

The circuit element layer DP-CL may be disposed on the base layer BL. The circuit element layer DP-CL may include a buffer layer BFL, a transistor TRI, a signal transfer area SCL, first to fifth insulating layers 10, 20, 30, 40, and 50, an electrode EE, and connection electrodes CNE1 and CNE2.

The buffer layer BFL may be disposed on the base layer BL. The buffer layer BFL may improve a bonding strength between the base layer BL and the semiconductor pattern. The buffer layer BFL may include a silicon oxide layer and a silicon nitride layer. The silicon oxide layer and the silicon nitride layer may be alternately stacked with each other.

The semiconductor pattern may be disposed on the buffer layer BFL. The semiconductor pattern may include polysilicon. However, embodiments are not limited thereto, and the semiconductor pattern may include amorphous silicon or metal oxide. FIG. 5 shows some semiconductor patterns by way of example, and the semiconductor patterns may be further disposed in the light-emitting areas PXA-R, PXA-G, and PXA-B (see FIG. 4). The semiconductor patterns may be arranged in a specific rule across the light-emitting areas PXA-R, PXA-G, and PXA-B. The semiconductor pattern may have different electrical properties depending on whether it is doped. The semiconductor pattern may include a first area with a high doping concentration and a second area with a low doping concentration. The first area may be doped with an N-type dopant or a P-type dopant. A P-type transistor may include the first area doped with the P-type dopant.

The first area may have greater conductivity than the second area and substantially functions as an electrode or a signal line. The second area may substantially correspond to an active region (or a channel) of the transistor. For example, a portion of the semiconductor pattern may be the active region of the transistor, another portion thereof may be a source region or a drain region of the transistor, and still another portion thereof may be a conductive region.

A source region S, an active region A, and a drain region D of the transistor TRI may be formed from the semiconductor pattern. FIG. 5 shows a portion of the signal transfer area SCL formed from the semiconductor pattern. For example, the signal transfer area SCL may be connected to the drain region D of the transistor TRI on a plane (or in plan view).

The first to fifth insulating layers 10, 20, 30, 40, and 50 may be disposed on the buffer layer BFL. The first to fifth insulating layers 10, 20, 30, 40, and 50 may be inorganic or organic layers.

The first insulating layer 10 may be disposed on the buffer layer BFL. The first insulating layer 10 may cover the source region S, the active region A, the drain region D, and the signal transfer area SCL of the transistor TRI disposed on the buffer layer BFL. A gate region G of the transistor TRI may be disposed on the first insulating layer 10. The second insulating layer 20 may be disposed on the first insulating layer 10 to cover the gate region G. The electrode EE may be disposed on the second insulating layer 20. The third insulating layer 30 may be disposed on the second insulating layer 20 to cover the electrode EE.

The first connection electrode CNE1 may be disposed on the third insulating layer 30. The first connection electrode CNE1 may be connected to the signal transfer area SCL via a contact hole CNT-1 extending through the first to third insulating layers 10, 20, and 30. The fourth insulating layer 40 may be disposed on the third insulating layer 30 to cover the first connection electrode CNE1. The fourth insulating layer 40 may be the organic layer.

The second connection electrode CNE2 may be disposed on the fourth insulating layer 40. The second connection electrode CNE2 may be connected to the first connection electrode CNE1 via a contact hole CNT-2 extending through the fourth insulating layer 40. The fifth insulating layer 50 may be disposed on the fourth insulating layer 40 to cover the second connection electrode CNE2. The fifth insulating layer 50 may be the organic layer.

The display element layer DP-OLED may be disposed on the circuit element layer DP-CL. The display element layer DP-OLED may include a light-emitting element ED, a sacrificial pattern SP, a pixel defining film PDL, and a partition wall (or bank) PW.

The light-emitting element ED may include an anode (or a first electrode) AE, a light-emission pattern EP, and a cathode (or a second electrode) CE. The light-emitting element ED may be disposed within a light-emitting opening OP-E and a partition wall opening (or bank opening) OP-P, which will be described later.

The anode AE may be disposed on the fifth insulating layer 50 of the circuit element layer DP-CL. The anode AE may be a transmissive electrode, a semi-transmissive electrode, or a reflective electrode. The anode AE may be connected to the second connection electrode CNE2 via a contact hole CNT-3 defined through the fifth insulating layer 50. Accordingly, the anode AE may be electrically connected to the signal transfer area SCL via the first and second connection electrodes CNE1 and CNE2, and may be electrically connected to a circuit element corresponding thereto. The anode AE may include a single-layer or multi-layer structure. The anode AE may include layers including ITO and Ag. For example, the anode AE may include a layer including ITO (hereinafter, referred to as a lower ITO layer), a layer including Ag disposed on the lower ITO layer (hereinafter, referred to as an Ag layer), and a layer including ITO disposed on the Ag layer (hereinafter, referred to as an upper ITO layer).

The sacrificial pattern SP may be disposed between the anode AE and the pixel defining film PDL. A sacrificial opening OP-S exposing a portion of a top surface (or upper surface) of the anode AE may be defined (or included) in the sacrificial pattern SP. The sacrificial opening OP-S may overlap the light-emitting opening OP-E, which will be described later.

The pixel defining film PDL may be disposed on the fifth insulating layer 50 of the circuit element layer DP-CL. The light-emitting opening OP-E may be defined (or included) in the pixel defining film PDL. The light-emitting opening OP-E may correspond to the anode AE, and the pixel defining film PDL may expose at least a portion of the anode AE via the light-emitting opening OP-E.

For example, the light-emitting opening OP-E may correspond to the sacrificial opening OP-S of the sacrificial pattern SP. According to an embodiment, the top surface of the anode AE may be spaced apart from the pixel defining film PDL in a cross-section with the sacrificial pattern SP interposed therebetween, thereby protecting the anode AE from damage during a formation process of the light-emitting opening OP-E.

On a plane (or in plan view), an area size of the light-emitting opening OP-E may be smaller than an area size of the sacrificial opening OP-S. For example, an inner surface of the pixel defining film PDL that defines the light-emitting opening OP-E may be closer to a center portion of the anode AE than an inner surface of the sacrificial pattern SP that defines the sacrificial opening OP-S. However, embodiments are not limited thereto, and the inner surface of the sacrificial pattern SP that defines the sacrificial opening OP-S may be substantially aligned with the inner surface of the pixel defining film PDL that defines the light-emitting opening OP-E. For example, the light-emitting area PXA may be viewed as an area of the anode AE exposed from the sacrificial opening OP-S corresponding thereto.

The pixel defining film PDL may include an inorganic insulating material. For example, the pixel defining film PDL may include silicon nitride (SiNₓ). The pixel defining film PDL may be disposed between the anode AE and the partition wall (or bank) PW to block the anode AE and the partition wall (or bank) PW from being electrically connected to each other.

The light-emission pattern EP may be disposed on the anode AE. The light-emission pattern EP may include a light-emitting layer including a light-emitting material. The light-emission pattern EP may further include a hole injection layer and a hole transport layer disposed between the anode AE and the light-emitting layer, or may further include an electron transport layer and an electron injection layer disposed on the light-emitting layer. The light-emission pattern EP may also be referred to as an ‘organic layer’ or an ‘intermediate layer’.

The light-emission pattern EP may be patterned by a tip portion defined (or formed) on the partition wall PW. Detailed content will be provided later in a description of a display panel manufacturing method. The light-emission pattern EP may be disposed inside the sacrificial opening OP-S and the light-emitting opening OP-E. However, this is shown as an example, and the light-emission pattern EP may be disposed inside at least one of the sacrificial opening OP-S, the light-emitting opening OP-E, and the partition wall opening OP-P. The light-emitting area PXA may be defined as an area where the top surface of the anode AE is exposed by the light-emitting opening OP-E.

The cathode CE may be disposed on the light-emission pattern EP. The cathode CE may be patterned by the tip portion defined (or formed) on the partition wall PW. At least a portion of the cathode CE may be disposed in the partition wall opening OP-P. FIG. 5 shows that cathode CE is disposed within the light-emitting opening OP-E and the partition wall opening OP-P as an example, but embodiments are not limited thereto. For example, the cathode CE may only be disposed within the partition wall opening OP-P.

The cathode CE may be in contact with the partition wall PW. For example, the cathode CE may extend along a first inner surface S-L1 of a first partition wall layer (or first bank layer) L1, and an end portion of the cathode CE may be in contact with the first partition wall layer L1. It is shown as an example in FIG. 5 that the cathode CE is in contact with the first inner surface S-L1 of the first partition wall layer L1 and the inner surface of the pixel defining film PDL, but embodiments are not limited thereto. For example, the cathode CE may be formed in contact only with the first inner surface S-L1 of the first partition wall layer L1.

The cathode CE may be conductive. The cathode CE may be made of a variety of materials as long as they are conductive, such as metal, transparent conductive oxide (TCO), or a conductive polymer material. For example, the cathode CE may include silver (Ag), magnesium (Mg), lead (Pb), copper (Cu), or compounds thereof.

The partition wall PW may be disposed on the pixel defining film PDL. The partition wall opening OP-P may be defined in the partition wall PW. The partition wall opening OP-P may overlap the light-emitting opening OP-E and expose at least a portion of the anode AE.

The partition wall PW may include multiple layers stacked sequentially. For example, the partition wall PW may include the first partition wall layer L1 and a second partition wall layer (or second bank layer) L2. The first partition wall layer L1 may be disposed on the pixel defining film PDL, and the second partition wall layer L2 may be disposed on the first partition wall layer L1. As shown in FIG. 5, a thickness of the first partition wall layer L1 may be greater than a thickness of the second partition wall layer L2, but embodiments are not limited thereto.

Each of the first partition wall layer L1 and the second partition wall layer L2 may include a conductive material. For example, the conductive material may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or alloys. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

The partition wall PW may have an undercut shape in the cross-section. At least one of the multiple layers of the partition wall PW may be depressed (or recessed) compared to the other layers, and thus the partition wall PW may include the tip portion. For example, the first partition wall layer L1 may have the undercut shape with respect to the second partition wall layer L2. The second partition wall layer L2 may include the tip portion protruding from the first partition wall layer L1 toward the light-emitting area PXA. For example, a second inner surface S-L2 of the second partition wall layer L2 may be closer to a center portion of the light-emitting area PXA than the first inner surface S-L1 of the first partition wall layer L1.

The second partition wall layer L2 may include a bottom surface (or lower surface) B-L2, the second inner surface S-L2, and a top surface (or upper surface) U-L2. The bottom surface (or lower surface) B-L2 of the second partition wall layer L2 may extend from the first inner surface S-L1 of the first partition wall layer L1, the second inner surface S-L2 may extend from the bottom surface (or lower surface) B-L2 in a direction away from the base layer BL, and the top surface (or upper surface) U-L2 may extend from the second inner surface S-L2 in a direction parallel to the bottom surface (or lower surface) B-L2. The second partition wall layer L2 may have an inverse-tapered shape. An angle formed between the bottom surface (or lower surface) B-L2 and the second inner surface S-L2 of the second partition wall layer L2 may be an obtuse angle. A length in a direction of the top surface (or upper surface) U-L2 of the second partition wall layer L2 may be greater than a length in the direction of the bottom surface (or lower surface) B-L2. For example, the direction may be perpendicular to a thickness direction of the base layer BL. For example, the direction may correspond to the first direction DR1 or the second direction DR2.

The partition wall PW may receive a driving voltage, and accordingly, the cathode CE may be electrically connected to the partition wall PW and receive the driving voltage.

The thin film encapsulation layer TFE may be disposed on the display element layer DP-OLED. The thin film encapsulation layer TFE may include a lower encapsulation inorganic pattern LIL, an encapsulation organic film OL, and an upper encapsulation inorganic film UIL.

The lower encapsulation inorganic pattern LIL may correspond to (or overlap) the light-emitting opening OP-E. The lower encapsulation inorganic pattern LIL may be disposed on the light-emitting element ED and may cover the light-emitting element ED. A portion of the lower encapsulation inorganic pattern LIL may be formed within the partition wall opening OP-P, and the remaining portion of the lower encapsulation inorganic pattern LIL may be formed on the partition wall PW. The lower encapsulation inorganic pattern LIL may be in contact with an entirety of the second inner surface S-L2 of the second partition wall layer L2.

The encapsulation organic film OL may be disposed on the lower encapsulation inorganic pattern LIL to cover the lower encapsulation inorganic pattern LIL. The encapsulation organic film OL may provide a flat top surface. The upper encapsulation inorganic film UIL may be disposed on the encapsulation organic film OL. The lower encapsulation inorganic pattern LIL and the upper encapsulation inorganic film UIL may protect the display element layer DP-OLED from moisture/oxygen, and the encapsulation organic film OL may protect the display element layer DP-OLED from foreign substances such as dust particles.

According to an embodiment, the light-emission patterns EP may be patterned and deposited in a pixel unit by the tip portion defined (or formed) on the partition wall PW. For example, the light-emission patterns EP may be commonly formed using an open mask, but are able to be easily divided into the pixel unit by the partition wall PW.

For example, when patterning the light-emission patterns EP using a fine metal mask, a support spacer protruding from the conductive partition wall must be disposed to support the fine metal mask. For example, because the fine metal mask is spaced from a base surface where the patterning is performed by a height of the partition wall and the spacer, there may be a limitation in realizing high resolution. For example, as the fine metal mask is in contact with the spacer, the foreign substances may remain on the spacer after the patterning process of the light-emission patterns EP, or the spacer may be damaged by a stamp on the fine metal mask. Accordingly, a defective display panel may be formed.

According to an embodiment, as the partition wall PW is included, physical separation of the light-emitting elements may be easily achieved. Accordingly, current leakage, a driving error, or the like between the adjacent light-emitting areas PXA-R, PXA-G, and PXA-B (see FIG. 4) may be prevented and independent driving of each light-emitting element may become available.

For example, by patterning the light-emission patterns EP without the mask in contact with the internal component within the display area DA (see FIG. 1B), the display panel DP with improved process reliability by reducing a defect rate may be provided. As the patterning is available even when the separate support spacer protruding from the partition wall PW is not disposed, the area sizes of the light-emitting areas PXA-R, PXA-G, and PXA-B may be reduced, so that the display panel DP that more readily achieves the high resolution may be provided.

For example, when manufacturing the large-area display panel DP, a process cost may be reduced by omitting production of a large-area mask, and the manufacturing may not be affected by defects that occur in the large-area mask, so that the display panel DP with the improved process reliability may be provided.

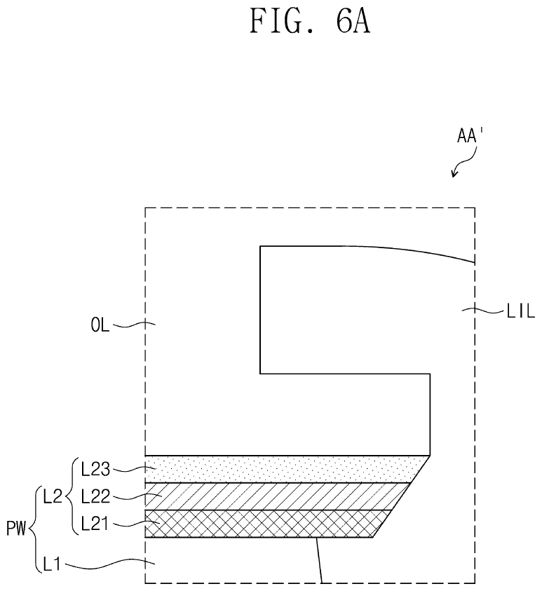

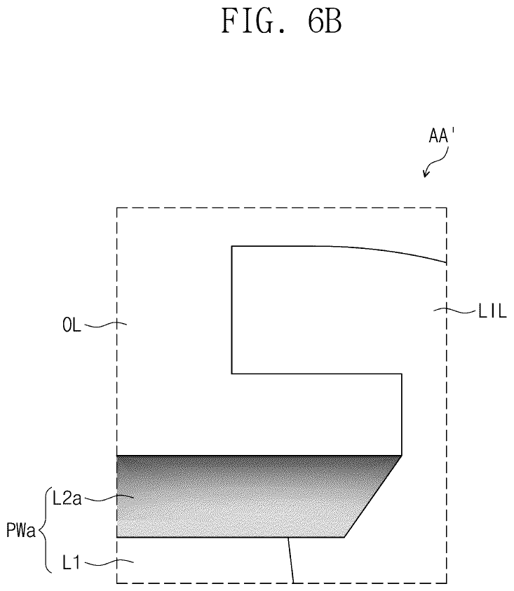

FIG. 6A is an enlarged schematic view of an area corresponding to an area AA′ in FIG. 5.

Referring to FIGS. 5 and 6A, the partition wall PW may include the first partition wall layer (or first bank layer) L1 and the second partition wall layer (or second bank layer) L2. In an embodiment, the second partition wall layer L2 may include sub-layers L21, L22, and L23. For example, the second partition wall layer L2 may include the first sub-layer L21, the second sub-layer L22, and the third sub-layer L23. In FIG. 6A, the three sub-layers L21, L22, and L23 are shown as an example, but the number of sub-layers is not limited thereto.

An etch rate of a sub-layer adjacent to the first partition wall layer L1 may be greater than an etch rate of a sub-layer adjacent to the encapsulation organic film OL. For example, an etch rate of the first sub-layer L21 may be greater than an etch rate of the second sub-layer L22, and the etch rate of the second sub-layer L22 may be greater than an etch rate of the third sub-layer L23. For example, the first sub-layer L21 may include tantalum (Ta), the second sub-layer L22 may include niobium (Nb), and the third sub-layer L23 may include titanium (Ti).

In a process of forming the partition wall PW, the sub-layer having the great etch rate adjacent to the first partition wall layer L1 may be etched more than the sub-layer having the relatively small etch rate adjacent to the encapsulation organic film OL. As a result, a length in the direction of the sub-layer adjacent to the first partition wall layer L1 may be smaller than a length in the direction of the sub-layer adjacent to the encapsulation organic film OL. For example, the direction may be perpendicular to the thickness direction of the base layer BL. For example, the direction may correspond to the first direction DR1 or the second direction DR2. For example, the second partition wall layer L2 may have the inverse-tapered shape.

FIG. 6B is an enlarged schematic view of an area corresponding to an area AA′ in FIG. 5.

Referring to FIGS. 5 and 6B, a partition wall (or bank) PWa may include the first partition wall layer (or first bank layer) L1 and a second partition wall layer (or second bank layer) L2a. In an embodiment, the second partition wall layer L2a may include an inorganic material. For example, the second partition wall layer L2a may include silicon nitride (SiNₓ). A density of the second partition wall layer L2a may decrease in a direction toward the first partition wall layer L1 from the encapsulation organic film OL. In the process of forming the partition wall PW, a portion of the less dense second partition wall layer L2a adjacent to the first partition wall layer L1 may be etched more than another portion of the relatively dense second partition wall layer L2a adjacent to the encapsulation organic film OL. As a result, a length of the portion of the second partition wall layer L2a adjacent to the first partition wall layer L1 may be smaller than a length of another portion of the second partition wall layer L2a adjacent to the encapsulation organic film OL. For example, the direction may be perpendicular to the thickness direction of the base layer BL. For example, the direction may correspond to the first direction DR1 or the second direction DR2. For example, the second partition wall layer L2 may have the inverse-tapered shape.

Referring to FIGS. 5 to 6B, as the second partition wall layer L2 has the inverse-tapered shape, a path for the foreign matter flowing into a space between the lower encapsulation inorganic pattern LIL and the partition wall PW may be lengthened, and a contact area between the lower encapsulation inorganic pattern LIL and the partition wall PW may increase. Therefore, a phenomenon in which the foreign substances are introduced via moisture into the space between the lower encapsulation inorganic pattern LIL and the partition wall PW may be reduced or eliminated. As a result, pixel defects (e.g., a dark spot, pixel shrinkage, and the like) of the display panel DP caused by the foreign substances may be reduced or eliminated.

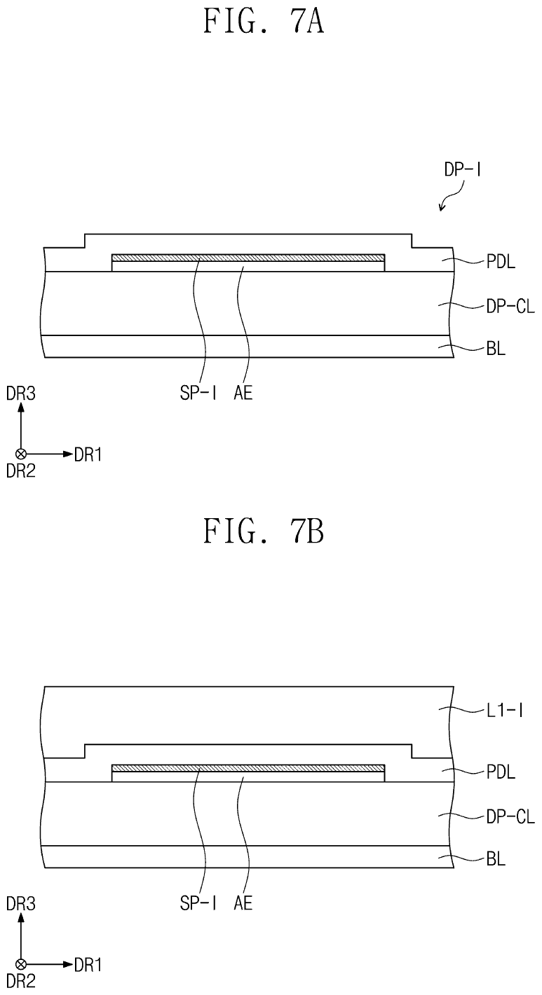

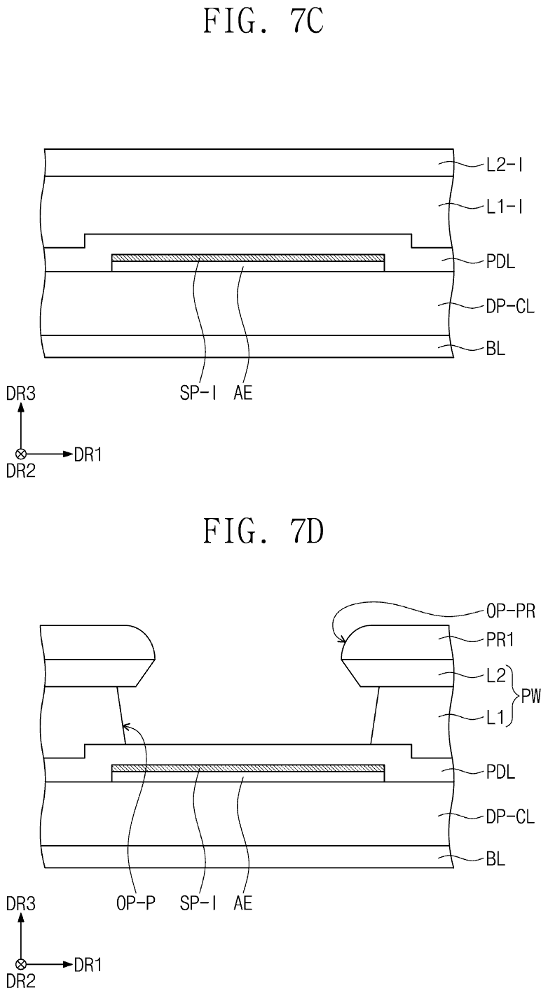

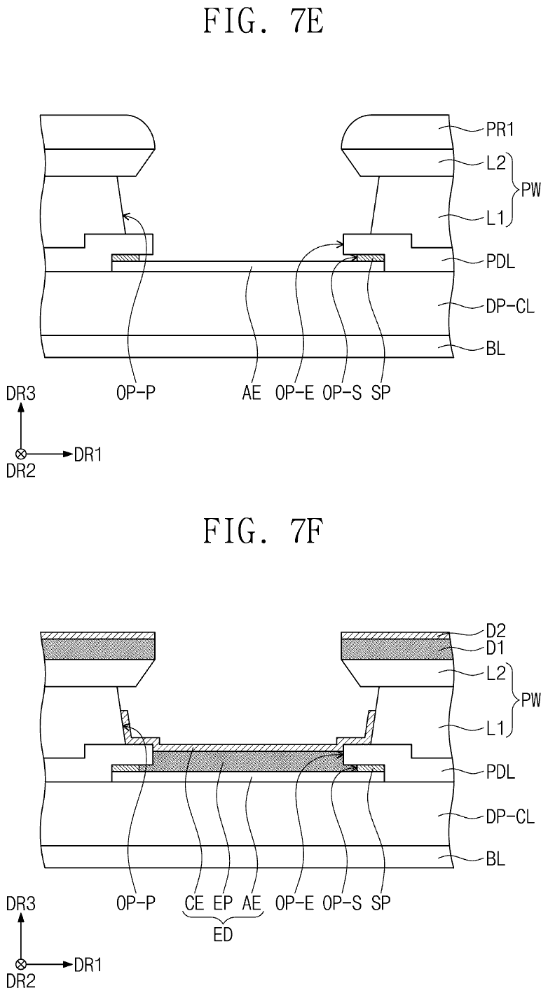

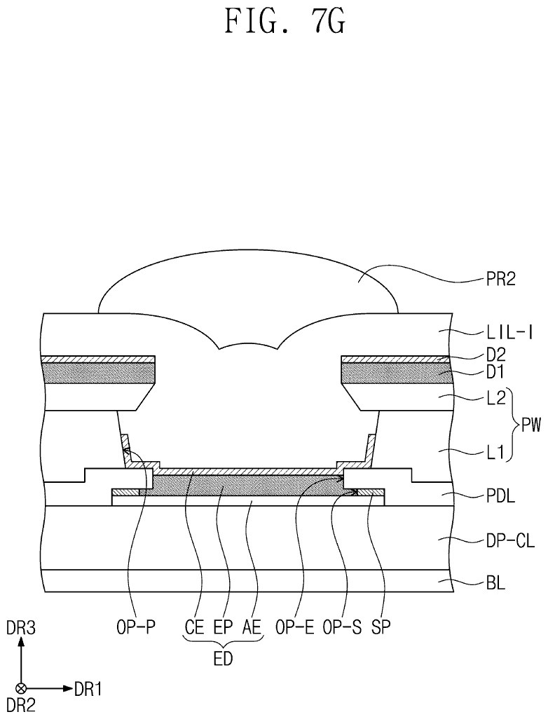

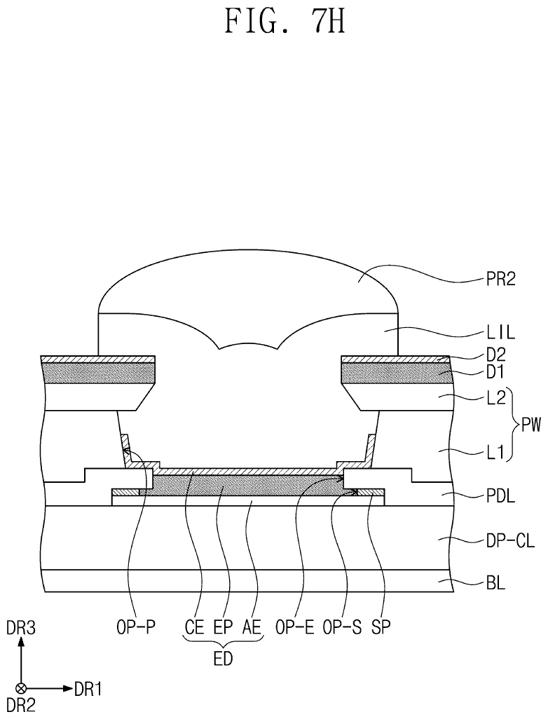

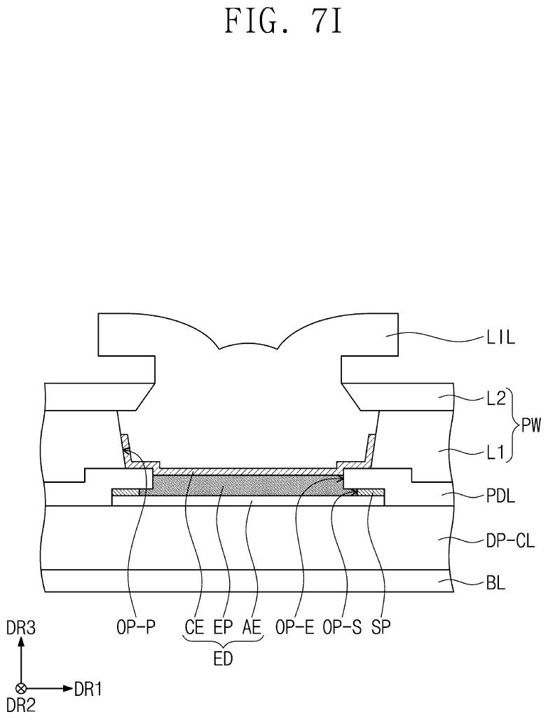

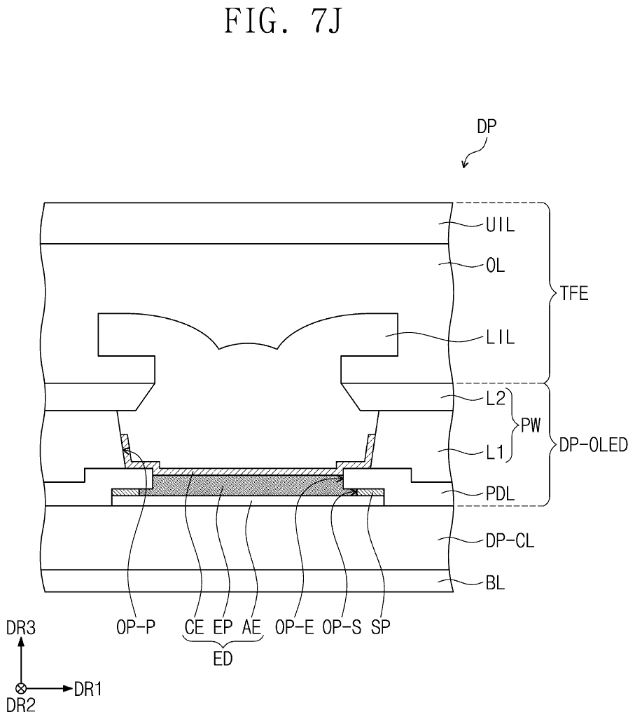

FIGS. 7A to 7J are schematic cross-sectional views showing some of steps of a display panel manufacturing method according to an embodiment. In describing FIGS. 7A to 7J, the same/similar components will be described using the same/similar reference numerals with reference to FIGS. 1 to 6B, and duplicate descriptions will be omitted for descriptive convenience.

The display panel manufacturing method according to an embodiment may include providing a preliminary display panel including the base layer and the pixel defining film disposed on the base layer, forming a first preliminary partition wall layer (or first preliminary bank layer) on the preliminary display panel, forming a second preliminary partition wall layer (or second preliminary bank layer) on the first preliminary partition wall layer, etching the first and second preliminary partition wall layers to form the partition wall having the partition wall opening and the portion having the inverse-tapered shape, etching the pixel defining film to define the light-emitting opening that overlaps the partition wall opening, and forming the light-emitting element within the light-emitting opening and the partition wall opening.

Hereinafter, a method for forming the one light-emitting element ED, the lower encapsulation inorganic pattern LIL that covers the light-emitting element ED, the encapsulation organic film OL, and the upper encapsulation inorganic film UIL will be described via FIGS. 7A to 7J. The display panel DP formed via FIGS. 7A to 7J may correspond to the display panel DP in FIG. 5.

Referring to FIG. 7A, the display panel manufacturing method may include providing a preliminary display panel DP-I. The preliminary display panel DP-I provided in an embodiment may include the base layer BL, the circuit element layer DP-CL, the anode AE, a preliminary sacrificial pattern SP-I, and the pixel defining film PDL.

The circuit element layer DP-CL may be formed via a typical manufacturing process of a circuit element of forming the insulating layer, the semiconductor layer, and the conductive layer via the scheme such as the coating and the deposition and selectively patterning the insulating layer, the semiconductor layer, and the conductive layer via the photolithography and etching processes to form the semiconductor pattern, the conductive pattern, the signal line, and the like.

The anode AE and the preliminary sacrificial pattern SP-I may be formed via the same patterning process. The pixel defining film PDL may be formed on the base layer BL, covering the anode AE and the preliminary sacrificial pattern SP-I.

Referring to FIG. 7B, the display panel manufacturing method may include forming a first preliminary partition wall layer (or first preliminary bank layer) L1-I on the preliminary display panel DP-I (see FIG. 7A). The first preliminary partition wall layer L1-I may be formed via a deposition process of a conductive material on the pixel defining film PDL. The first preliminary partition wall layer L1-I may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or alloys. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

Referring to FIG. 7C, the display panel manufacturing method may include forming a second preliminary partition wall layer (or second preliminary bank layer) L2-I on the first preliminary partition wall layer L1-I. The second preliminary partition wall layer L2-I may be formed via a deposition process of a conductive material on the first preliminary partition wall layer L1-I. The second preliminary partition wall layer L2-I may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or alloys. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

Referring to FIG. 7D, the display panel manufacturing method may include forming a first photoresist layer PR1. The first photoresist layer PR1 may be formed by forming a preliminary photoresist layer on the second preliminary partition wall layer L2-I and then patterning the preliminary photoresist layer using a photo mask. A photo opening OP-PR may be defined in the first photoresist layer PR1 via a patterning process. The photo opening OP-PR may overlap the anode AE.

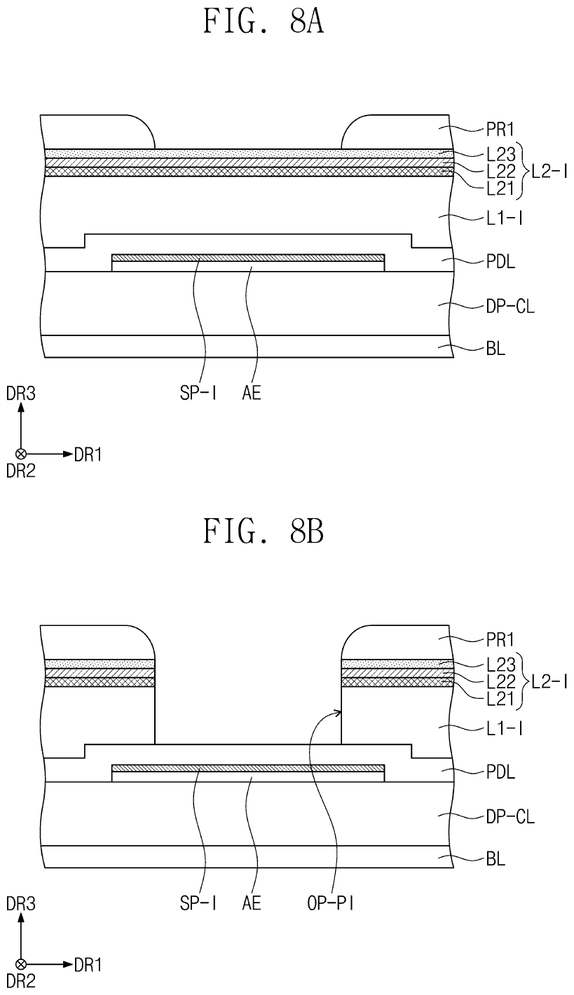

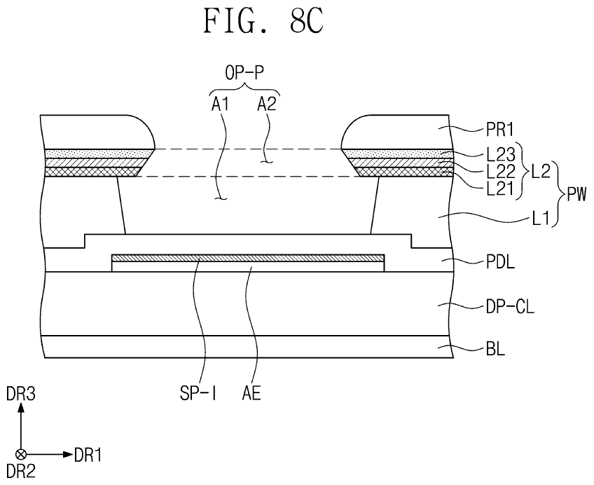

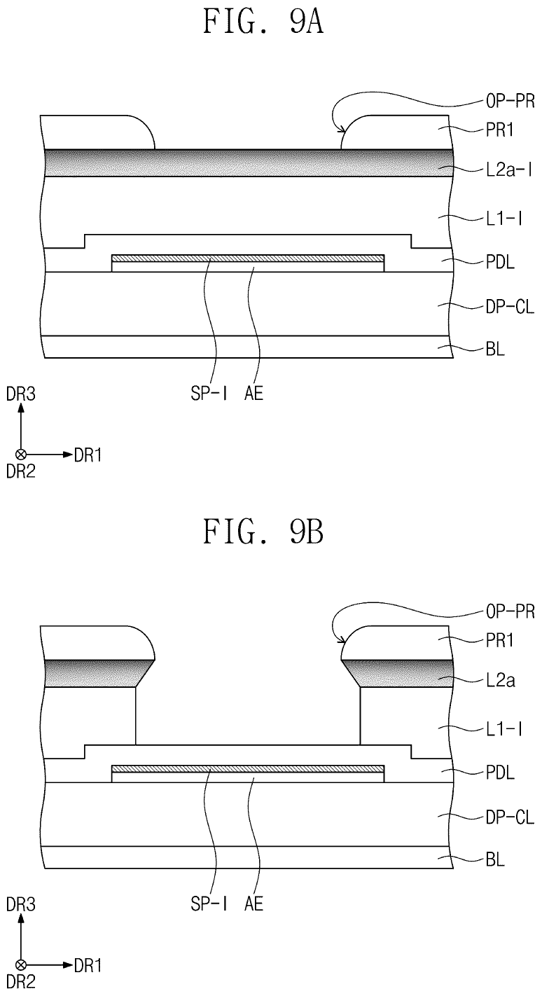

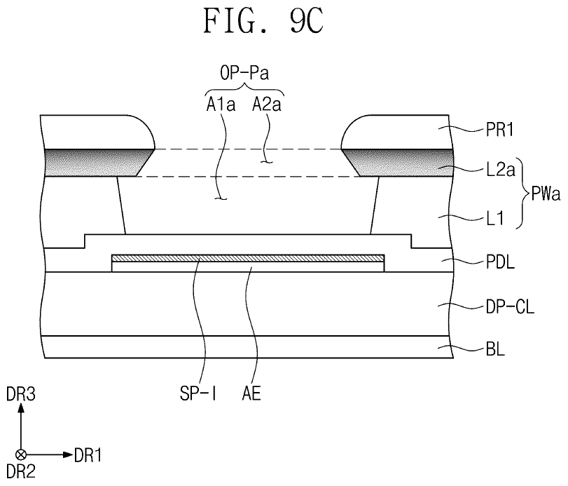

Thereafter, the display panel manufacturing method may include etching the first and second preliminary partition wall layers L1-I and L2-I (see FIG. 7C) to form the partition wall PW having the partition wall opening OP-P and the portion having the inverse-tapered shape. The forming of the partition wall PW may include forming the first partition wall layer L1 and the second partition wall layer L2. The second partition wall layer L2 may have the inverse-tapered shape. The length in the direction of the top surface (or upper surface) U-L2 (see FIG. 5) of the second partition wall layer L2 may be greater than the length in the direction of the bottom surface (or lower surface) B-L2 (see FIG. 5). For example, the direction may be perpendicular to the thickness direction of the base layer BL. For example, the direction may correspond to the first direction DR1 or the second direction DR2. Detailed content will be provided later in FIGS. 8A to 9C.

Thereafter, referring to FIG. 7E, the display panel manufacturing method may include etching the pixel defining film PDL to define the light-emitting opening OP-E that overlaps the partition wall opening OP-P.

The etching of the pixel defining film PDL may include dry etching the pixel defining film PDL using the first photoresist layer PR1 and the partition wall PW (for example, the second partition wall layer L2) as a mask. In the pixel defining film PDL, a portion that does not overlap the first photoresist layer PR1 and the partition wall PW may be etched and removed. As a result, the light-emitting opening OP-E that overlaps the partition wall opening OP-P may be defined in the pixel defining film PDL.

For example, the display panel manufacturing method may include etching the preliminary sacrificial pattern SP-I (see FIG. 7D) to form the sacrificial pattern SP with the sacrificial opening OP-S that overlaps the light-emitting opening OP-E.

The etching of the preliminary sacrificial pattern SP-I may include wet etching the preliminary sacrificial pattern SP-I using the first photoresist layer PR1 and the partition wall PW (for example, the second partition wall layer L2) as a mask. In the preliminary sacrificial pattern SP-I, a portion that does not overlap the first photoresist layer PR1 and the partition wall PW may be etched and removed. As a result, the sacrificial pattern SP may be formed from the preliminary sacrificial pattern SP-I. The sacrificial opening OP-S may be defined in the sacrificial pattern SP.

The etching process of the sacrificial pattern SP may be performed in an environment where an etch selectivity between the sacrificial pattern SP and the anode AE is high, and accordingly, the anode AE may be prevented from being etched together. For example, by placing the sacrificial pattern SP, which has a greater etch rate than the anode AE, between the pixel defining film PDL and the anode AE, the anode AE may be prevented from being etched together during the etching process and from being damaged.

Thereafter, referring to FIG. 7F, the display panel manufacturing method may include removing the first photoresist layer PR1 (see FIG. 7E) and then forming the light-emitting element ED within the light-emitting opening OP-E and the partition wall opening OP-P. The forming of the light-emitting element ED may include forming the light-emission pattern EP and forming the cathode CE.

The forming of the light-emission pattern EP may include a deposition process of the light-emitting layer. For example, the forming of the light-emission pattern EP may include performing thermal evaporation of the light-emitting layer. The light-emitting layer may be separated by the tip portion formed on the partition wall PW and deposited inside the light-emitting opening OP-E and on the partition wall PW. A portion of the light-emitting layer formed within the light-emitting opening OP-E may form the light-emission pattern EP, and a portion of the light-emitting layer formed on the partition wall PW may form a first dummy layer D1. For example, the light-emission pattern EP may be formed to overlap the partition wall opening OP-P on the anode AE.

The first dummy layer D1 formed together in the forming of the light-emission pattern EP may include an organic material. For example, the first dummy layer D1 may include the same material as the light-emission pattern EP. The first dummy layer D1 may be formed simultaneously with the light-emission pattern EP by a single process, and may be formed separately from the light-emission pattern EP by the undercut shape of the partition wall PW.

The forming of the cathode CE may include a deposition process of a cathode layer. For example, the forming of the cathode CE may include sputtering the cathode layer. The cathode layer may be separated by the tip portion formed on the partition wall PW and deposited inside the partition wall opening OP-P and on the partition wall PW. A portion of the cathode layer formed within the partition wall opening OP-P may form the cathode CE, and a portion of the cathode layer formed on the partition wall PW may form a second dummy layer D2. For example, the cathode CE may be formed to overlap the partition wall opening OP-P on the light-emission pattern EP. For example, the cathode CE may be formed to contact the first inner surface S-L1 (see FIG. 5) of the first partition wall layer L1 and to extend along the first inner surface of the first partition wall layer L1.

The second dummy layer D2 formed together in the forming of the cathode CE may include a conductive material. For example, the second dummy layer D2 and the cathode CE may include the same material. The second dummy layer D2 may be formed simultaneously with the cathode CE by a single process, and may be formed separately from the cathode CE by the undercut shape of the partition wall PW.

The anode AE, the light-emission pattern EP, and the cathode CE may be sequentially stacked along the third direction DR3. The anode AE, the light-emission pattern EP, and the cathode CE may form the light-emitting element ED.

Referring to FIGS. 7G to 7H, the display panel manufacturing method may include forming the lower encapsulation inorganic pattern LIL.

Referring to FIG. 7G, the forming of the lower encapsulation inorganic pattern LIL may include depositing a lower encapsulation inorganic layer LIL-I. In an embodiment, the lower encapsulation inorganic layer LIL-I may be formed by a chemical vapor deposition (CVD) process. The lower encapsulation inorganic layer LIL-I may be formed to cover the cathode CE and the partition wall PW. A portion of the lower encapsulation inorganic layer LIL-I may fill the partition wall opening OP-P.

Thereafter, the display panel manufacturing method may include forming a second photoresist layer PR2. In the forming of the second photoresist layer PR2, the second photoresist layer PR2 may be formed by forming the preliminary photoresist layer and then patterning the preliminary photoresist layer using a photo mask. Via the patterning process, the second photoresist layer PR2 may be formed in a pattern shape corresponding to the light-emitting element ED.

Referring to FIG. 7H, the forming of the lower encapsulation inorganic pattern LIL may include removing a portion of the lower encapsulation inorganic layer LIL-I (see FIG. 7G) that does not overlap the light-emitting element ED.

The removing of the portion of the lower encapsulation inorganic layer LIL-I that does not overlap the light-emitting element ED may include dry etching the lower encapsulation inorganic layer LIL-I using the second photoresist layer PR2 as a mask. A portion of the lower encapsulation inorganic layer LIL-I that does not overlap the second photoresist layer PR2 may be removed, and the lower encapsulation inorganic pattern LIL may be formed on a remaining portion of the lower encapsulation inorganic layer LIL-I that has not been etched.

Referring to FIG. 7I, the display panel manufacturing method may include removing the second photoresist layer PR2 (see FIG. 7I) and then removing the dummy layers D1 and D2 (see FIG. 7H). The second dummy layer D2 among the dummy layers D1 and D2 may be removed via wet etching, and the first dummy layer D1 among the dummy layers D1 and D2 may be removed with a stripper.

Thereafter, referring to FIG. 7J, the display panel manufacturing method may include forming the encapsulation organic film OL and the upper encapsulation inorganic film UIL to complete the display panel DP. The encapsulation organic film OL may be formed by applying an organic material using an inkjet scheme, but embodiments are not limited thereto. The encapsulation organic film OL provides a flat top surface. Thereafter, the upper encapsulation inorganic film UIL may be formed by depositing an inorganic material. Accordingly, the display panel DP including the base layer BL, the circuit element layer DP-CL, the display element layer DP-OLED, and the thin film encapsulation layer TFE may be formed.

FIGS. 8A to 8C are schematic cross-sectional views showing some of steps of a display panel manufacturing method according to an embodiment. In describing FIGS. 8A to 8C, the same/similar components will be described using the same/similar reference numerals with reference to FIGS. 1 to 7J, and duplicate descriptions will be omitted for descriptive convenience. FIGS. 8A to 8C correspond to the processes of FIGS. 7C and 7D, and the display panel DP formed via FIGS. 8A to 8C corresponds to FIG. 6A.

Referring to FIGS. 7C and 8A, the display panel manufacturing method of an embodiment may include forming the second preliminary partition wall layer L2-I on the first preliminary partition wall layer L1-I. The forming of the second preliminary partition wall layer L2-I on the first preliminary partition wall layer L1-I may include depositing the first sub-layer L21 on the first preliminary partition wall layer L1-I, depositing the second sub-layer L22 on the first sub-layer L21, and depositing the third sub-layer L23 on the second sub-layer L22. The etch rate of the first sub-layer L21 may be greater than the etch rate of the second sub-layer L22, and the etch rate of the second sub-layer L22 may be greater than the etch rate of the third sub-layer L23. For example, the first sub-layer L21 may include tantalum (Ta), the second sub-layer L22 may include niobium (Nb), and the third sub-layer L23 may include titanium (Ti).

Referring to FIGS. 7D and 8B, the etching of the first and second preliminary partition wall layers L1-I and L2-I to form the partition wall PW (see FIG. 8C) having the partition wall opening OP-P (see FIG. 8C) may include dry etching the first and second preliminary partition wall layers L1-I and L2-I to define a preliminary partition wall opening OP-PI.

The defining of the preliminary partition wall opening OP-PI may include dry etching the first preliminary partition wall layer L1-I and the second preliminary partition wall layer L2-I using the first photoresist layer PR1 as a mask. Portions of the first and second preliminary partition wall layers L1-I and L2-I that do not overlap the first photoresist layer PR1 may be etched and removed. For example, the preliminary partition wall opening OP-PI may be defined in the removed portions that overlap the photo opening OP-PR. The dry etching process may be performed in an etching environment where etch rates of the first preliminary partition wall layer L1-I and the second preliminary partition wall layer L2-I are substantially the same. Accordingly, an inner surface of the first preliminary partition wall layer L1-I and an inner surface of the second preliminary partition wall layer L2-I that define the preliminary partition wall opening OP-PI may be substantially aligned.

Thereafter, referring to FIGS. 7D and 8C, the etching of the first and second preliminary partition wall layers L1-I and L2-I (see FIG. 8B) to form the partition wall PW having the partition wall opening OP-P may include wet etching the first and second preliminary partition wall layers L1-I and L2-I to form the first partition wall layer L1 and the second partition wall layer L2 having the inverse-tapered shape.

The wet etching of the first and second preliminary partition wall layers L1-I and L2-I may include wet etching the first and second preliminary partition wall layers L1-I and L2-I using the first photoresist layer PR1 as a mask. Accordingly, the first partition wall layer L1 depressed (or recessed) inward and the second partition wall layer L2 having the inverse-tapered shape may be formed, and the partition wall opening OP-P may be defined (or formed).

The first sub-layer L21 with the great etch rate may be etched more than the second and third sub-layers L22 and L23 with the relatively small etch rates, and the third sub-layer L23 with the small etch rate may be etched relatively less than the first and second sub-layers L21 and L22 with the great etch rates. As a result, the length in the direction of the sub-layer may decrease in the direction toward the first partition wall layer L1. For example, the second partition wall layer L2 may have the inverse-tapered shape.

For example, the wet etching process may be performed in an environment where an etch selectivity between the first preliminary partition wall layer L1-I and the second preliminary partition wall layer L2-I is high. Accordingly, an inner surface of the partition wall PW defining the partition wall opening OP-P may have the undercut shape in the cross-section. For example, as the etch rate of the first preliminary partition wall layer L1-I for an etching solution is greater than the etch rate of the second preliminary partition wall layer L2-I, the first preliminary partition wall layer L1-I may be mainly etched. Accordingly, the first inner surface S-L1 (see FIG. 5) of the first partition wall layer L1 may be formed to be more depressed (or recessed) inward than the second inner surface S-L2 (see FIG. 5) of the second partition wall layer L2. The tip portion may be formed on the partition wall PW by a portion of the second partition wall layer L2 that protrudes more than the first partition wall layer L1.

The partition wall opening OP-P may include a first area A1 defined by the first inner surface S-L1 of the first partition wall layer L1 and a second area A2 defined by the second inner surface S-L2 of the second partition wall layer L2, and a length in a direction perpendicular to the base layer BL of the first area A1 may be greater than a length in the direction perpendicular to the base layer BL of the second area A2.

FIGS. 9A to 9C are schematic cross-sectional views showing some of steps of a display panel manufacturing method according to an embodiment. In describing FIGS. 9A to 9C, the same/similar components will be described using the same/similar reference numerals with reference to FIGS. 1 to 7J, and duplicate descriptions will be omitted for descriptive convenience. FIGS. 9A to 9C correspond to the processes in FIGS. 7C and 7D, and the display panel DP formed via FIGS. 9A to 9C corresponds to FIG. 6B.

Referring to FIGS. 7C and 9A, the display panel manufacturing method of an embodiment may include forming a second preliminary partition wall layer L2a-I on the first preliminary partition wall layer L1-I. The forming of the second preliminary partition wall layer L2a-I on the first preliminary partition wall layer L1-I may include depositing an inorganic material at a first speed and depositing the inorganic material at a second speed. The first speed may be higher than the second speed. For example, a deposition device may deposit the inorganic material on the first preliminary partition wall layer L1-I at a gradually decreasing speed. As a result, a density of the second preliminary partition wall layer L2a-I may increase in a direction away from the first preliminary partition wall layer L1-I. As a result, the second preliminary partition wall layer L2a-I may include the inorganic material. For example, the second preliminary partition wall layer L2a-I may include silicon nitride (SiNₓ).

Referring to FIGS. 7D and 9B, etching the first and second preliminary partition wall layers L1-I and L2a-I (see FIG. 9A) to form the partition wall PWa (see FIG. 9C) having a partition wall opening (or bank opening) OP-Pa (see FIG. 9C) may include dry etching the first and second preliminary partition wall layers L1-I and L2a-I to form the second partition wall layer L2a having an inverse-tapered shape.

The forming of the second partition wall layer L2a may include dry etching the first preliminary partition wall layer L1-I and the second preliminary partition wall layer L2a-I using the first photoresist layer PR1 as a mask. Portions of the first and second preliminary partition wall layers L1-I and L2a-I that do not overlap the first photoresist layer PR1 may be etched and removed. For example, a portion of the second partition wall layer L2a adjacent to the first partition wall layer L1, which has a low density, may be more etched than another portion of the second partition wall layer L2a, which has a relatively high density. As a result, a length in a direction of the second partition wall layer L2a may decrease in the direction toward the first partition wall layer L1. For example, the second partition wall layer L2a may have the inverse-tapered shape.

Thereafter, referring to FIGS. 7D and 9C, the etching of the first and second preliminary partition wall layers L1-I and L2a-I (see FIG. 9A) to form the partition wall PWa having the partition wall opening OP-Pa may include wet etching the first preliminary partition wall layer L1-I to form the first partition wall layer L1.

The wet etching of the first preliminary partition wall layer L1-I may include wet etching the first preliminary partition wall layer L1-I using the first photoresist layer PR1 as a mask. Accordingly, the first partition wall layer L1 depressed (or recessed) inward may be formed, and the partition wall opening OP-P may be defined (or formed).

The wet etching process may be performed in an environment where an etch selectivity between the first preliminary partition wall layer L1-I and the second partition wall layer L2a is high. Accordingly, an inner surface of the partition wall PWa defining the partition wall opening OP-Pa may have the undercut shape in a cross-section. For example, as an etch rate of the first preliminary partition wall layer L1-I for the etching solution is greater than an etch rate of the second partition wall layer L2a, the first preliminary partition wall layer L1-I may be etched (e.g., mainly etched). Accordingly, the first inner surface S-L1 (see FIG. 5) of the first partition wall layer L1 may be formed to be more depressed (or recessed) inward than the second inner surface S-L2 (see FIG. 5) of the second partition wall layer L2a. A tip portion may be formed on the partition wall PWa by a portion of the second partition wall layer L2a that protrudes more than the first partition wall layer L1.

The partition wall opening OP-Pa may include a first area Ala defined by the first inner surface S-L1 of the first partition wall layer L1 and a second area A2a defined by the second inner surface S-L2 of the second partition wall layer L2a. A length in the direction perpendicular to the base layer BL of the first area Ala may be greater than a length in the direction perpendicular to the base layer BL of the second area A2a.

According to the above description, as the second partition wall layer has the inverse-tapered shape, the path for the foreign substances flowing into the space between the lower encapsulation inorganic pattern and the partition wall may be lengthened, and the contact area between the lower encapsulation inorganic pattern and the partition wall may increase. Therefore, the phenomenon in which the foreign substances are introduced via moisture into the space between the lower encapsulation inorganic pattern and the partition wall may be reduced or eliminated. As a result, the pixel defects (e.g., the dark spot, the pixel shrinkage, and the like) of the display panel caused by the foreign substances may be reduced or eliminated.

Although the description has been made with reference to an embodiment, those skilled in the art or have ordinary knowledge in the relevant technical field will understand that the present disclosure may be modified and changed in various ways without departing from the ideas and the technical scope of the disclosure described in the claims to be described later. Therefore, the technical scope of the disclosure should not be limited to the content described in the detailed description of the present document, but should be determined by the claims.

What is claimed is:

1. A display panel comprising:
a base layer;
a pixel defining film disposed on the base layer and including a light-emitting opening;
a bank disposed on the pixel defining film and including a bank opening overlapping the light-emitting opening; and
a light-emitting element including an anode, a light-emission pattern, and a cathode in contact with the bank, wherein
the light-emitting element is disposed in the light-emitting opening and the bank opening, and
the bank includes a first bank layer disposed on the pixel defining film, and a second bank layer disposed on the first bank layer and having an inverse-tapered shape.

2. The display panel of claim 1, wherein the second bank layer includes a tip portion protruding from the first bank layer.

3. The display panel of claim 1, wherein
the second bank layer includes a lower surface extending from a first inner surface of the first bank layer, a second inner surface extending from the lower surface in a direction away from the base layer, and an upper surface extending from the second inner surface in a direction parallel to the lower surface, and
an angle formed between the lower surface and the second inner surface is an obtuse angle.

4. The display panel of claim 3, wherein
a light-emitting area, in which the anode is exposed, is defined by the light-emitting opening,
the second inner surface is closer to a center portion of the light-emitting area than the first inner surface.

5. The display panel of claim 3, wherein a length in a direction of the upper surface of the second bank layer is greater than a length in the direction of the lower surface, and the direction is perpendicular to a thickness direction of the base layer.

6. The display panel of claim 3, further comprising:
a lower encapsulation inorganic pattern covering the light-emitting element,
wherein the lower encapsulation inorganic pattern is in contact with an entirety of the second inner surface of the second bank layer.

7. The display panel of claim 6, further comprising:
an encapsulation organic film covering the lower encapsulation inorganic pattern.

8. The display panel of claim 7, wherein the second bank layer includes a plurality of sub-layers.

9. The display panel of claim 8, wherein an etch rate of a sub-layer adjacent to the first bank layer is greater than an etch rate of a sub-layer adjacent to the encapsulation organic film.

10. The display panel of claim 8, wherein a length in a direction of a sub-layer adjacent to the first bank layer is smaller than a length in the direction of a sub-layer adjacent to the encapsulation organic film,
wherein the direction is perpendicular to a thickness direction of the base layer.

11. The display panel of claim 7, wherein the second bank layer includes an inorganic material.

12. The display panel of claim 11, wherein a density of the second bank layer decreases in a direction toward the first bank layer from the encapsulation organic film.

13. A method for manufacturing a display panel, the method comprising:
providing a preliminary display panel including a base layer and a pixel defining film disposed on the base layer;
forming a first preliminary bank layer on the preliminary display panel;
forming a second preliminary bank layer on the first preliminary bank layer;
etching the first and second preliminary bank layers to form a bank including a bank opening and a portion having an inverse-tapered shape;
etching the pixel defining film to form a light-emitting opening overlapping the bank opening; and
forming a light-emitting element in the light-emitting opening and the bank opening.

14. The method of claim 13, wherein the etching of the first and second preliminary bank layers to form the bank including the bank opening and the portion having the inverse-tapered shape includes:
forming a first bank layer and a second bank layer, wherein a length in a direction of an upper surface of the second bank layer is greater than a length in the direction of a lower surface and the direction is perpendicular to a thickness direction of the base layer.

15. The method of claim 13, wherein the forming of the second preliminary bank layer on the first preliminary bank layer includes:
depositing a first sub-layer on the first preliminary bank layer;
depositing a second sub-layer on the first sub-layer; and
depositing a third sub-layer on the second sub-layer,
wherein an etch rate of the first sub-layer is greater than an etch rate of the second sub-layer, and the etch rate of the second sub-layer is greater than an etch rate of the third sub-layer.

16. The method of claim 15, wherein the etching of the first and second preliminary bank layers to form the bank including the bank opening includes:
dry etching the first and second preliminary bank layers to form a preliminary bank opening; and
wet etching the first and second preliminary bank layers to form a first bank layer and a second bank layer having an inverse-tapered shape.

17. The method of claim 13, wherein the forming of the second preliminary bank layer on the first preliminary bank layer includes:
depositing an inorganic material at a first speed; and
depositing the inorganic material at a second speed,
wherein the first speed is higher than the second speed.

18. The method of claim 17, wherein a density of the second preliminary bank layer increases in a direction away from the first preliminary bank layer.

19. The method of claim 17, wherein the etching of the first and second preliminary bank layers to form the bank including the bank opening includes:
dry etching the first and second preliminary bank layers to form a second bank layer having an inverse-tapered shape; and
wet etching the first preliminary bank layer to form a first bank layer.

20. The method of claim 14, wherein the bank opening includes a first area defined by a first inner surface of the first bank layer and a second area defined by a second inner surface of the second bank layer, and a length in a direction perpendicular to the base layer of the first area is greater than a length in the direction perpendicular to the base layer of the second area.
